(19) United States
(12) Patent Application Publication
(10) Pub. No.: US 2011/0086213 A1
(43) Pub. Date: Apr. 14, 2011

(54) METHOD OF PRODUCING A SILICON CARBIDE BULK SINGLE CRYSTAL WITH THERMAL TREATMENT, AND LOW-IMPEDANCE MONOCRYSTALLINE SILICON CARBIDE SUBSTRATE

(75) Inventors: THOMAS STRAUBINGER, ERLANGEN (DE); MICHAEL VOGEL, NURNBERG (DE); ANDREAS WOHLFART, ERLANGEN (DE)

(73) Assignee: SICRYSTAL AG, ERLANGEN (DE)

(21) Appl. No.: 12/902,704

(22) Filed: Oct. 12, 2010

(30) Foreign Application Priority Data
Oct. 9, 2009 (DE) 10 2009 048 868.5

(51) Int. Cl. C30B 15/14; C01B 31/36; B32B 9/00

(52) U.S. Cl. 428/220; 117/3; 423/345

(57) ABSTRACT

A silicon carbide bulk single crystal is produced at a growth temperature of up to 2200° C. by sublimation growth and is subjected to thermal aftertreatment after the sublimation growth. The bulk single crystal is brought to an aftertreatment temperature that is higher than a growth temperature. Very low-stress and low-dislocation SiC substrates can be produced from such a SiC bulk single crystal, the substrates additionally having a particularly low electrical resistivity. The SiC bulk single crystal is positioned within an SiC powder before the thermal aftertreatment and it is completely surrounded by the SiC powder during the thermal aftertreatment.

### CROSS-REFERENCE TO RELATED APPLICATION

This application claims the priority, under 35 U.S.C. §119, of German patent application DE 10 2009 048 868.5, filed Oct. 9, 2009; the prior application is herewith incorporated by reference in its entirety.

### BACKGROUND OF THE INVENTION

### Field of the Invention

The invention relates to a method for producing an SiC bulk single crystal, and to a monocrystalline SiC substrate.

Owing to its outstanding physical, chemical, electrical and optical properties, the semiconductor material silicon carbide (SiC) is used, inter alia, as a starting material for power electronic semiconductor components, for radiofrequency components and for specific light-emitting semiconductor components. SiC substrates (=SiC wafers) having the largest possible substrate diameter, having the highest possible quality and also the lowest possible electrical resistance are required for those components. High-quality SiC bulk single crystals are the basis for this.

Such SiC bulk single crystals are generally produced by way of physical vapor deposition, in particular by means of a sublimation method described, for instance, in U.S. Pat. No. 6,773,505 B2 and in German patent DE 199 31 332 C2. The wafer-type monocrystalline SiC substrates are sliced from these SiC bulk single crystals and then, in the context of component production, are provided with at least one epitaxial layer, which in particular also consists of SiC. In general, defects from the SiC substrate are passed on to the applied epitaxial layer and thus lead to an impairment of the component properties. The quality of the components is therefore substantially dependent on that of the grown SiC bulk single crystal and of the SiC substrates obtained therefrom. In order to produce an SiC substrate having a low electrical resistance, a dopant gas, for example nitrogen (N₂), is added to the SiC growth gas phase during the vapor deposition for producing the SiC bulk single crystal. The electrical resistance of the growing SiC bulk single crystal decreases as the nitrogen content in the SiC growth gas phase increases. However, limits are imposed on that. After the conclusion of sublimation growth, mechanical stresses arise on account of the axial temperature gradient that is inevitably present in the grown SiC bulk single crystal. The mechanical stresses are compensated for only partly by means of dislocation formations and/or dislocation movements during the cooling phase. As the proportion of nitrogen increases, these compensating dislocation movements are impeded to an ever greater extent, such that the tendency toward cracking during the subsequent further processing of the SiC bulk single crystal or of the SiC substrates produced therefrom increases with the nitrogen content. In order to avoid this undesirable cracking, state of the art SiC substrates have a nitrogen content of at most, which leads to an electrical resistivity of at least approximately 24 mΩcm.

The prior art publications WO 2006/041660 A2, JP 2004 131 328 A, JP 2008 103 650 A, JP 2006 290 705 A, and WO 2009/003100 A1 respectively describe methods for the thermal aftertreatment of a sublimation-grown SiC bulk single crystal or of substrate wafers sliced from such an SiC bulk single crystal by sawing. The temperatures of these thermal aftertreatments are in each case approximately 2000° C. or higher. Therefore, these aftertreatment temperatures are at least in part also higher than the growth temperature prevailing during the sublimation growth. An article by H.-J. Rost, et al. “Influence of nitrogen doping on the properties of 4H—SiC single crystals grown by physical vapor transport”, Journal of Crystal Growth 257, 2003, pages 75 to 83, describes an investigation of 4H—SiC single crystals having a high nitrogen doping. The increased undulation of the SiC substrate at such concentrations and also a comparatively high anisotropy of the electrical resistivity are indicated as disadvantageous.

### SUMMARY OF THE INVENTION

It is accordingly an object of the invention to provide a production process for an SiC volume single crystal and a low-resistance monocrystalline SiC substrate which overcome the above-mentioned disadvantages of the heretofore-known devices and methods of this general type and which provides, simply, for an improved method for producing an SiC bulk single crystal and also an improved monocrystalline SiC substrate.

With the foregoing and other objects in view there is provided, in accordance with the invention, a method of producing an SiC bulk single crystal. The method comprises the following steps:

growing an SiC bulk single crystal at a growth temperature of up to 2200° C. by way of sublimation growth; subjecting the SiC bulk single crystal to a thermal aftertreatment following the sublimation growth, and thereby bringing the SiC bulk single crystal to an aftertreatment temperature that is higher than the growth temperature; and

placing the SiC bulk single crystal within an SiC powder prior to the thermal aftertreatment and completely surrounding the SiC bulk single crystal with the SiC powder during the thermal aftertreatment.

In other words, the objects are achieved, in accordance with the invention, by growing the crystal at a growth temperature of up to 2200° C. in a sublimation growth process, and subjecting the SiC bulk single crystal to thermal aftertreatment after the sublimation growth, wherein it is brought to an aftertreatment temperature that is higher than the growth temperature. The SiC bulk single crystal is positioned within an SiC powder before the thermal aftertreatment. It is completely surrounded by the SiC powder during the thermal aftertreatment.

It has been recognized that the quality of the grown SiC bulk single crystal can be considerably improved if the SiC bulk single crystal is subjected to a thermal aftertreatment in an, in particular, substantially isothermal temperature field after the conclusion of sublimation growth and, in particular, before further processing, wherein the aftertreatment temperature provided in this case is preferably set to a value of more than 2200° C. Above this growth temperature, mechanical stresses possibly present in the SiC bulk single crystal are reduced particularly well by thermally activated dislocation movements. A further effect of the thermal aftertreatment is the reduction of the dislocation density, which likewise arises as a result of the thermally activated dislocation movements and/or mutual quenching of (complementary) dislocations. Therefore, both the mechanical stresses and the global dislocation density within the SiC bulk single crystal are reduced on account of the thermal aftertreatment above the growth temperature that is provided according to the invention. Dislocations in the crystal lattice are defects which occur during the SiC sublimation growth and which are likewise undesirable. Therefore, a considerably better crystal quality is obtained by virtue of the thermal aftertreatment. Moreover, it is possible to dope the SiC bulk single crystal with a proportion of nitrogen which, in particular, is higher than in the case of the previously known SiC bulk single crystals. The nitrogen doping in the SiC bulk single crystal thus produced is, in particular, at least 1×10¹⁹ cm⁻³ and preferably high enough that the SiC bulk single crystal has an electrical resistivity of, in particular, at least 20 mΩcm. The mechanical stresses possibly established on account of this are completely eliminated again or at least considerably reduced during the thermal aftertreatment, such that further processing without an appreciable risk of cracking is readily possible.

At high temperatures, in particular at those above the growth temperature, there is a certain probability that Si and C atoms will evaporate or sublimate at the surface of the SiC bulk single crystal subjected to thermal aftertreatment. This can take place non-stoichiometrically, in particular. Silicon leaves the crystal lattice more easily and more rapidly than carbon. The surface quality of the SiC bulk single crystal can deteriorate as a result. In order to prevent such non-stoichiometric evaporation or sublimation from the surface, the SiC bulk single crystal is embedded in SiC powder during the thermal aftertreatment. The (non-stoichiometric) evaporation or sublimation then takes place primarily from the SiC powder. In particular, this also produces a silicon counter-pressure that counteracts non-stoichiometric evaporation or sublimation from the surface of the embedded SiC bulk single crystal. Consequently, the SiC bulk single crystal can be subjected to thermal aftertreatment for longer in order to reduce mechanical stresses.

Overall, therefore, mechanically very low-stress and low-defect and electrically very low-impedance SiC bulk single crystals can be produced by means of the growth method according to the invention. In particular, the SiC bulk single crystals thus produced can be dimensioned with a significantly lower electrical resistivity than conventionally produced SiC bulk single crystals. SiC bulk single crystals produced according to the invention are distinguished by a higher quality and can be used further in a more flexible fashion, in particular for the production of semiconductor components.

In accordance with one particular configuration, a global temperature difference within the SiC bulk single crystal during the thermal aftertreatment is set to at most 10 K, in particular to at most 5 K. Within the SiC bulk single crystal, therefore, the temperature difference is then at most 10 K, or 5 K, wherein the regions with the two temperature extrema can lie at any desired location within the SiC bulk single crystal. During the thermal aftertreatment, therefore, a preferably substantially isothermal or homogeneous temperature field with temperature fluctuations of, in particular, at most 5‰, preferably at most 2.5‰, is present in the SiC bulk single crystal. Under these substantially isothermal conditions, the mechanical stresses within the SiC bulk single crystal compensate for one another particularly well.

In accordance with a further particular consideration, the SiC bulk single crystal grows in the direction of a central longitudinal axis. This therefore involves the growth direction of the SiC bulk single crystal, which is also the axial direction thereof. During the thermal aftertreatment, an axial temperature difference measured in the direction of the central longitudinal axis within the SiC bulk single crystal is set to at most 2 K, in particular to at most 1 K. During the sublimation growth, a comparatively high temperature gradient is provided owing to the material transport from the SiC source to the growing SiC bulk single crystal in the axial direction, such that the formation of mechanical stresses can occur to an increased extent in this direction. In this respect, it is advantageous to provide particularly small temperature differences of, in particular, at most 1‰, preferably at most 0.5‰, in the axial direction during the thermal aftertreatment, in order to particularly promote compensation of the mechanical stresses in this direction and in order as far as possible to prevent instances of re-formation of stress precisely in this direction.

In accordance with a further particular configuration, a cooling rate at the end of the thermal aftertreatment is set to at most 5 K/min, in particular to at most 1 K/min. The cooling also takes place, in particular, under substantially isothermal conditions, that is to say with a locally substantially homogeneous temperature field. The very low cooling rate is used to prevent mechanical stresses from forming anew during the cooling phase after the conclusion of the thermal aftertreatment.

In accordance with a further particular configuration, an aftertreatment duration of at least 24 hours and of, in particular, at most 72 hours is provided for the thermal aftertreatment. The longer the thermal aftertreatment lasts, the better the mechanical stresses compensate for one another. A large part of this compensation has already been concluded after 24 hours. An aftertreatment duration of 48 hours is particularly efficient. It represents a good compromise between the compensation of as many mechanical stresses as possible and a shortest possible time expenditure. Moreover, an excessively long aftertreatment duration is associated with an increased risk of undesirable evaporation or sublimation of Si and C atoms from the surface of the SiC bulk single crystal.

In accordance with a further particular configuration, the SiC powder used is one which, at least before the thermal aftertreatment, is composed of SiC grains, of which 50% by weight (=percent by weight) have a grain size having a maximum grain diameter of at most 500 μm, in particular of at most 100 μm. All of the SiC grains taken together then have an advantageously large total surface area, whereby the (non-stoichiometric) evaporation or sublimation from the SiC powder and hence the build-up of the desired silicon counterpressure are promoted.

In accordance with a further particular configuration, the SiC powder used is one which, at least before the thermal aftertreatment, has a molar ratio of a carbon (C) fraction to a silicon (Si) fraction in the range of between 0.9 and 1.1, preferably of 1. The SiC powder then has an elemental composition which is identical or at least comes very close to the stoichiometric ratio of the elements in the SiC bulk single crystal. This ensures that the SiC bulk single crystal is not impaired, at least not critically, on account of its embedding into the SiC powder during the thermal aftertreatment. Moreover, the SiC powder then brings about the silicon counterpressure particularly precisely, said silicon counterpressure preventing non-stoichiometric evaporation or sublimation from the surface of the SiC bulk single crystal very well.

In accordance with a further particular configuration, the SiC bulk single crystal is accommodated in a crucible completely surrounded by a thermal insulation material for the thermal aftertreatment. What is thereby achieved is that the SiC bulk single crystal is situated in a substantially isothermal or homogeneous temperature field during the thermal aftertreatment. Local temperature fluctuations—even very small ones—are prevented very well by the thermal insulation. Optionally, the thermal insulation can have at least one small cutout for measuring the temperature in the interior.

With the above and other objects in view there is also provided, in accordance with the invention, a monocrystalline SiC substrate with a substrate main surface and a substrate thickness, wherein an electrical resistivity determined for an arbitrary 4 mm²-size, in particular square partial area of the substrate main surface and relative to the substrate thickness is less than 20 mΩcm.

In particular, the low resistivity value can also hold true with respect to the substrate main surface overall. The SiC substrate according to the invention therefore has a particularly low electrical resistivity and is outstandingly suitable for applications requiring a low-impedance substrate behavior. Hitherto, SiC substrates have often been ineligible for such applications on account of the excessively high resistance, inter alia. Consequently, the substrate according to the invention can be used particularly advantageously, for example as a substrate for producing semiconductor components. Monocrystalline SiC substrates having such a low electrical resistance have not existed hitherto. They can only be produced from SiC bulk single crystals which have been produced in accordance with the above-described method according to the invention or the configurations thereof.

In accordance with one particular configuration, the resistivity is at most 15 mΩcm. Therefore, the monocrystalline SiC substrate has an even lower electrical resistance. This additionally improves the quality and capability of further use of the SiC substrate.

In accordance with a further particular configuration, the substrate main surface has a diameter of at least 100 mm, and preferably of at least 150 mm. The greater the substrate diameter, the more efficiently the monocrystalline SiC substrate can be used further for the production of semiconductor components, for example. The production costs for the semiconductor components decrease as a result. An SiC substrate having such a large diameter can advantageously also be used for producing relatively large semiconductor components having e.g. a base area of approximately 1 cm². Since the risk of mechanical stresses and cracking increases as the substrate diameter increases, it is particularly favorable, precisely in the case of large SiC substrates which additionally have a comparatively high dopant concentration in order to obtain a low electrical resistance, if the above-described thermal aftertreatment is carried out during the production process.

In accordance with a further particular configuration, the substrate main surface has a diameter of at least 150 mm, and, in addition, the substrate thickness is at most 500 μm. The smaller the substrate thickness, the higher the number of substrates that can be obtained from an SiC bulk single crystal. As a result of this, too, the efficiency during the production of semiconductor components is increased and the production costs for the semiconductor components decrease. Such large and thin SiC substrates can be obtained, in particular, from a very low-stress SiC bulk single crystal. Otherwise, precisely in the case of a very small substrate thickness, cracks and/or complete destruction of the SiC substrate can occur. In this respect, the above-described thermal aftertreatment for stress reduction also promotes the production of thin SiC substrates.

In accordance with a further particular configuration, the substrate main surface has a diameter of at least 150 mm and, in addition, a global dislocation density determined for the entire substrate main surface is at most 10⁴ cm⁻². In this case, the global dislocation density specifies, in particular, the dislocations which are present in the crystal structure of the monocrystalline SiC substrate and can be detected at the substrate main surface overall, to be precise e.g. for dislocations of one type or else for all dislocations independently of the respective type. In this case, therefore, the dislocation density is an area-related variable. Despite the large substrate diameter and also despite the low electrical resistivity, on account of the thermal aftertreatment of the SiC bulk single crystal, the SiC substrate has only very few of such dislocations which impair the capability of further use.

During the crystal growth process, dislocations often form in the growing SiC bulk single crystal. Said dislocations can move at high aftertreatment temperatures, in particular at temperatures above the growth temperature, and in this case also mutually quench one another. This movement takes place e.g. on account of the so-called glide mechanism. Overall, the dislocation density can be reduced in this way.

At low dopings, that is to say in particular at a comparatively high electrical resistivity of more than 20 mΩcm, the dislocation movement is possible more easily and a dislocation movement and hence a reduction of the dislocation densities can already be achieved at low aftertreatment temperatures and with short heat treatment times (=duration of the thermal aftertreatment).

By contrast, at high dopings, that is to say in particular at a comparatively low electrical resistivity of less than 20 mΩcm, or preferably of less than 15 mΩcm, the dislocation movement is made more difficult. Higher aftertreatment temperatures and longer heat treatment times are then necessary in order to achieve a significant reduction of the dislocation density by dislocation movement and quenching. These high aftertreatment temperatures and long heat treatment times can preferably be realized if the SiC bulk single crystal is completely embedded in SiC powder after sublimation growth for the purpose of the thermal aftertreatment. Otherwise, the SiC bulk single crystal would evaporate non-stoichiometrically at least at its surface.

Other features which are considered as characteristic for the invention are set forth in the appended claims.

Although the invention is illustrated and described herein as embodied in a production method for an SiC bulk single crystal by means of a thermal treatment and low-impedance monocrystalline SiC substrate, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE SEVERAL VIEWS OF THE DRAWING

FIG. 1 shows an exemplary embodiment of a sublimation system for producing an SiC bulk single crystal by sublimation growth;

FIG. 2 shows an exemplary embodiment of a configuration for the thermal aftertreatment of an SiC bulk single crystal produced by way of the sublimation growth system in accordance with FIG. 1; and

FIG. 3 is cross-sectional illustration of an exemplary embodiment of a low-impedance monocrystalline SiC substrate produced from an SiC bulk single crystal that has been grown in the system of FIG. 1 and subjected to thermal aftertreatment by way of the configuration in accordance with FIG. 2.

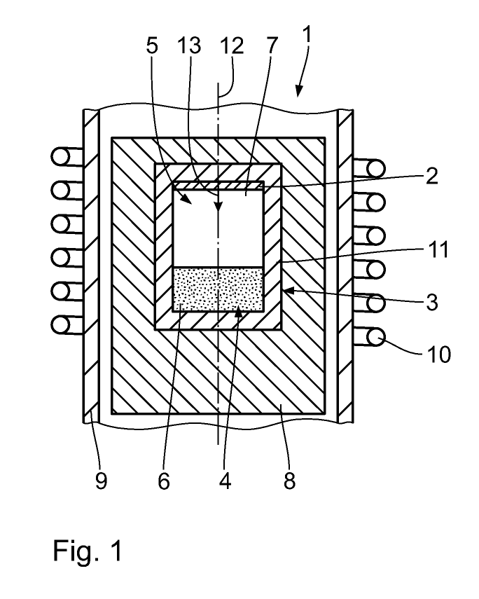

Parts which correspond to one another are provided with the same reference symbols in FIGS. 1 to 3.

### DETAILED DESCRIPTION OF THE INVENTION

Referring now to the figures of the drawing in detail and first, particularly, to FIG. 1 thereof, there is shown an exemplary embodiment of a sublimation growth system 1 for producing an SiC bulk single crystal 2 by sublimation growth. The sublimation growth system 1 includes a growth crucible 3, which comprises an SiC supply region 4 and also a crystal growth region 5. The SiC supply region 4 contains for example pulverulent SiC source material 6, with which the SiC supply region 4 of the growth crucible 3 is filled as a prefabricated starting material before the beginning of the growth process.

On an inner wall of the growth crucible 3 opposite the SiC supply region 4, a defect-free or at least extremely low-defect seed crystal (not explicitly illustrated in FIG. 1) is attached in the crystal growth region 5. The SiC bulk single crystal 2 to be grown grows on the seed crystal by way of deposition from an SiC growth gas phase 7 that forms in the crystal growth region 5. The growing SiC bulk single crystal 2 and the seed crystal have approximately the same diameter. There arises, if at all, a deviation of at most 10% by which the diameter of the seed crystal is less than the diameter of the SiC bulk single crystal 2.

In the exemplary embodiment in accordance with FIG. 1, the growth crucible 3 consists of an electrically and thermally conductive graphite crucible material having a density of, e.g., at least 1.75 g/cm³. A thermal insulation layer 8 is arranged around it. The thermal insulation layer consists, by way of example, of a foam-like graphite insulation material, the porosity of which is, in particular, significantly higher than that of the graphite crucible material.

The thermally insulated growth crucible 3 is positioned within a tubular container 9, which, in the exemplary embodiment, is embodied as a quartz glass tube and forms an autoclave or reactor. In order to heat the growth crucible 3, an inductive heating device in the form of a heating coil 10 is arranged around the container 9. The heating coil 10 couples an electric current inductively into an electrically conductive crucible wall 11 of the growth crucible 3. Said electric current flows substantially as a circulating current in the circumferential direction within the circular- and hollow-cylindrical crucible wall 11 and heats up the growth crucible 3 in the process. As necessary, the relative position between the heating coil 10 and the growth crucible 3 can be altered axially, that is to say in the direction of a central longitudinal axis 12 of the growing SiC bulk single crystal 2, in particular in order to set and, if appropriate, also to alter the temperature or the temperature profile within the growth crucible 3. The growth crucible 3 is heated to growth temperatures of more than 2000° C., in particular to approximately 2200° C., by means of the heating coil 10.

The SiC growth gas phase 7 in the crystal growth region 5 is supplied by the SiC source material 6. The SiC growth gas phase 7 contains at least gas constituents in the form of Si, Si₂C and SiC₂ (=SiC gas species). The transport of the SiC source material 6 to the growth interface at the growing SiC bulk single crystal 2 takes place along a temperature gradient. The temperature within the growth crucible 3 decreases toward the growing SiC bulk single crystal 2. The SiC bulk single crystal 2 grows in a growth direction 13, which is oriented from the top downward, that is to say from the upper wall of the growth crucible 3 to the SiC supply region 4 arranged at the bottom, in the exemplary embodiment shown in FIG. 1. The growth direction 13 runs parallel to the central longitudinal axis 12. Since the growing SiC bulk single crystal 2 is arranged concentrically within the sublimation growth system 1 in the exemplary embodiment shown, the central longitudinal axis 12 can also be assigned to the sublimation growth system 1 overall.

In addition, the SiC growth gas phase 7 also contains dopants, not shown in greater detail in the illustration in accordance with FIG. 1, which are nitrogen (N₂) in the exemplary embodiment. The feed is effected either in gaseous fashion or by means of the SiC source material 6, which is then pretreated accordingly. In this case, the proportion of nitrogen in the SiC growth gas phase 7 is set such that the nitrogen doping of the growing SiC bulk single crystal 2 is high enough that the growing SiC bulk single crystal 2 has a very low electrical resistivity of only approximately 15 mΩcm.

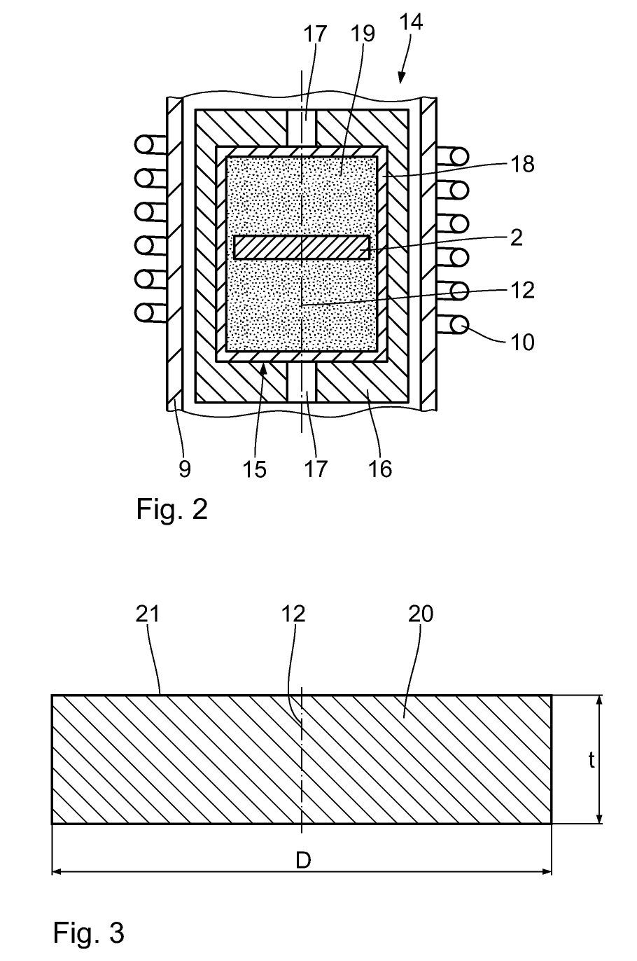

FIG. 2 illustrates an exemplary embodiment of an aftertreatment configuration 14 constructed very similarly to the sublimation growth system 1. This likewise contains a crucible 15, which consists of a graphite material and which is surrounded by a thermal insulation 16, similar to the thermal insulation layer 8. The crucible 15 thermally insulated in this way is in turn arranged in the tubular container 9 (=autoclave), which is surrounded by the inductive heating coil 10. The thermal insulation 16 contains two pyrometer channels 17, which are intended for detecting a temperature in the interior of the thermal insulation 16. In order to influence the temperature field within the thermal insulation 16 as little as possible and in order to ensure a temperature field that is as isothermal as possible, the cutouts provided in the thermal insulation material for forming the pyrometer channels 17 are made only very small. They have a diameter of at most 15 mm.

However, the pyrometer channels 17 are only optional. They can also be omitted as necessary. In that case, the crucible 15 is completely surrounded by thermal insulation material and the temperature setting and temperature control are effected indirectly by way of the power regulation of the heating coil 10.

The SiC bulk single crystal 2 produced by means of the sublimation growth system 1 is arranged in the interior of the crucible 15. In contrast to the sublimation growth system 1, however, the SiC bulk single crystal 2 in the case of the aftertreatment configuration 14 is not situated in direct contact with the crucible wall 18, not even indirectly by way of a seed crystal. Instead, the SiC bulk single crystal 2 is arranged in a manner spaced apart at all points from the crucible wall 18 with otherwise approximately the same orientation as in the sublimation growth system 1, that is to say with substantially parallel orientation of the central longitudinal axis 12 with respect to the central axis of the heating coil 10 and also concentrically with respect to the heating coil 10. The SiC bulk single crystal 2 is positioned within an SiC powder 19, with which the crucible 15 is filled, and is completely surrounded by said SiC powder 19. In this respect, the transverse dimensions, i.e. the radial dimensions relative to the central longitudinal axis 12, of the crucible 15 are larger than those of the growth crucible 3.

The SiC powder 19 has a molar ratio of carbon to silicon (C:Si) of approximately 1 corresponding to the stoichiometric ratio of carbon and silicon in the SiC bulk single crystal 2. Moreover, the SiC powder 19 is composed of powder grains, of which 50% by weight have a maximum grain diameter of at most 100 μm.

The SiC bulk single crystal 2 is subjected to thermal aftertreatment in the aftertreatment configuration 14, wherein it is exposed to a temperature of above 2200° C., that is to say to a temperature above the growth temperature, for a treatment duration of typically 48 hours. In this case, mechanical stresses produced within the SiC bulk single crystal 2, for example during the cooling phase after the conclusion of the sublimation growth in the sublimation growth system 1, are compensated for again by thermally activated dislocation movements. The dislocation density is also reduced at the same time. During the thermal aftertreatment, the SiC bulk single crystal 2 is situated in a temperature field that is as homogeneous as possible, that is to say as isothermal as possible, with a maximum temperature difference relative to the complete SiC bulk single crystal 2 of typically 5 K and an axial temperature difference relative to the axial direction, that is to say the growth direction 13, of typically 1 K. After the conclusion of the thermal treatment, the cooling phase takes place comparatively slowly with a cooling rate of typically 1 K/min.

The quality of the SiC bulk single crystal 2 has improved considerably on account of this thermal aftertreatment. The SiC bulk single crystal is then a very low-stress and low-dislocation crystal.

From an SiC bulk single crystal 2 produced by means of the sublimation growth system 1 and then subjected to thermal treatment by means of the aftertreatment configuration 14, it is possible to produce monocrystalline SiC substrates 20 that likewise have very favorable mechanical and electrical properties. They are large and thin and, in the same way as the SiC bulk single crystal, very low-stress and low-defect substrates. Moreover, with an electrical resistivity of 15 mΩcm, they have a comparatively low impedance. All of such monocrystalline SiC substrates 20, one exemplary embodiment of which is shown in a cross-sectional illustration in accordance with FIG. 3, are obtained from the SiC bulk single crystal 2 by being sliced or sawn axially progressively as wafers perpendicularly to the growth direction 13 or to the central longitudinal axis 12. Besides the low electrical resistance already mentioned, these SiC substrates 20 also have a very low dislocation density and at most 10⁴ cm⁻². Moreover, their respective substrate main surface 21 has a large substrate diameter D of 150 mm, whereas a substrate thickness t has the low value of only approximately 500 μm.

1. A method of producing an SiC bulk single crystal, the method which comprises:
growing an SiC bulk single crystal at a growth temperature of up to 2200° C. by way of sublimation growth;
subjecting the SiC bulk single crystal to a thermal aftertreatment following the sublimation growth, and thereby bringing the SiC bulk single crystal to an aftertreatment temperature that is higher than the growth temperature; and
placing the SiC bulk single crystal within an SiC powder prior to the thermal aftertreatment and completely surrounding the SiC bulk single crystal with the SiC powder during the thermal aftertreatment.

2. The method according to claim 1, which comprises setting a global temperature difference within the SiC bulk single crystal during the thermal aftertreatment to at most 10 K.

3. The method according to claim 2, which comprises setting the global temperature difference within the SiC bulk single crystal during the thermal aftertreatment to no more than 5 K.

4. The method according to claim 1, which comprises growing the SiC bulk single crystal in a direction of a central longitudinal axis, and setting an axial temperature difference measured in the direction of the central longitudinal axis within the SiC bulk single crystal during the thermal aftertreatment to at most 2 K.

5. The method according to claim 4, which comprises setting the axial temperature difference in the direction of the central longitudinal axis during the thermal aftertreatment to no more than 1 K.

6. The method according to claim 1, which comprises cooling the SiC single crystal at a cooling rate at the end of the thermal aftertreatment of at most 5 K/min.

7. The method according to claim 6, which comprises setting the cooling rate at the end of the thermal aftertreatment to no more than 1 K/min.

8. The method according to claim 1, which comprises carrying out the thermal aftertreatment during an aftertreatment duration of at least 24 hours.

9. The method according to claim 8, which comprises selecting the aftertreatment duration to last no more than 72 hours.

10. The method according to claim 1, wherein the SiC powder, before the thermal aftertreatment, is composed of SiC grains, of which 50% by weight have a grain size with a maximum grain diameter of at most 500 μm.

11. The method according to claim 10, wherein the maximum grain diameter is no more than 100 μm.

12. The method according to claim 1, which comprises providing the SiC powder with a molar ratio between a C fraction and an Si fraction in a range between 0.9 and 1.1 prior to the thermal aftertreatment.

13. The method according to claim 11, which comprises setting the molar ratio of C to Si at 1.

14. The method according to claim 1, which comprises performing the thermal aftertreatment with the SiC bulk single crystal accommodated in a crucible completely surrounded by a thermal insulation material.

15. A monocrystalline SiC substrate, comprising:
a substrate main surface and a substrate thickness, wherein an electrical resistivity determined for an arbitrary 4 mm² partial area of the substrate main surface and relative to the substrate thickness is less than 20 mΩcm.

16. The SiC substrate according to claim 15, wherein the partial area is a square area.

17. The SiC substrate according to claim 15, wherein the resistivity is less than 15 mΩcm.

18. The SiC substrate according to claim 15, wherein said substrate main surface has a diameter of at least 100 mm.

19. The SiC substrate according to claim 15, wherein said diameter is at least 150 mm.

20. The SiC substrate according to claim 15, wherein said substrate main surface has a diameter of at least 150 mm and the substrate thickness is at most 500 μm.

21. The SiC substrate according to claim 15, wherein the substrate main surface has a diameter of at least 150 mm and a global dislocation density determined for an entire said substrate main surface is at most 10⁴ cm⁻².
